(19) United States
(12) Patent Application Publication
(10) Pub. No.: US 2016/0358566 A1
(43) Pub. Date: Dec. 8, 2016

(54) SHIFT REGISTER UNIT AND DRIVING METHOD THEREOF, GATE DRIVING CIRCUIT AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Jinyu LI, Beijing (CN); Xue CAO, Beijing (CN)

(21) Appl. No.: 15/031,174

(22) PCT Filed: Nov. 10, 2015
(86) PCT No.: PCT/CN2015/094223

§ 371 Date: Apr. 21, 2016

(30) Foreign Application Priority Data
Jun. 8, 2015 (CN) 201510309520.5

(51) Int. Cl. G09G 3/36; G11C 19/28

(52) U.S. Cl. CPC G09G 3/3648; G11C 19/28; G09G 2300/0426; G09G 2330/021; G09G 2310/0286; G09G 2310/0289; G09G 2310/08

(57) ABSTRACT

A shift register unit and a driving method thereof, a gate driving circuit and a display device. In the shift register unit, an input module outputs a pull-up control signal to a pull-up module based on a first DC voltage signal and a start signal, the pull-up module outputs a shift signal via a first output port and output a start signal for a next stage of shift register unit via a second output port, a pull-down control module outputs a pull-down control signal to a pull-down module, the pull-down module outputs to the pull-up module a pull-down signal for the first output port, the second output port and a pull-up point, a reset module resets the pull-up module. DC voltages are used as input signals of the pull-up module and the pull-down control module, which is stable and has a small power consumption.

### CROSS-REFERENCE TO RELATED APPLICATION

This application claims the benefit and priority of Chinese Patent Application No. 201510309520.5 filed Jun. 8, 2015. The entire disclosure of the above application is incorporated herein by reference.

### FIELD

The present disclosure relates to the field of display technology, and particularly, to a shift register unit and a driving method thereof, a gate driving circuit and a display device.

### BACKGROUND

A traditional manner for driving a display device is driving pixels on the display panel with an external drive chip to display an image. In order to reduce the number of elements and the manufacturing cost, in recent years, the technology of directly preparing a drive circuit structure onto a panel (e.g., integrating a gate driving circuit onto a liquid crystal panel (Gate On Array, abbreviated as GOA) has become a main stream.

Currently, such a drive circuit is usually driven with AC signals. Thus, there is unavoidable signal delay effect. Driving with AC signals increases power consumption of the drive circuit and decreases driving capabilities, and can hardly be applied to a large size liquid crystal display device.

### SUMMARY

The embodiments of the disclosure provide a shift register unit and a driving method thereof, a gate driving circuit and a display device. DC voltage is used as input signals of the main transistor, leading to stable outputs, strong driving capabilities and a significant reduction of power consumption by the circuit in the pull-up phase and the pull-down phase.

According to a first aspect of the disclosure, there is provided a shift register unit comprising an input module, a pull-down control module, a pull-down module, a pull-up module and a reset module, wherein the input module is connected with the pull-up module, and configured to output a pull-up control signal to the pull-up module based on a first DC voltage signal and a start signal, wherein the pull-up module is configured to output a shift signal via a first output port and output a start signal for a next stage of shift register unit via a second output port, based on a second DC voltage signal and a clock signal, wherein the pull-down control module is connected with the pull-down module and the pull-up module, and configured to output a pull-down control signal to the pull-down module based on the second DC voltage signal, a third DC voltage signal and the clock signal, wherein the pull-down module is connected with the pull-up module, and configured to output to the pull-up module a pull-down signal for the first output port, the second output port and a pull-up point, and wherein the reset module is connected with the pull-up module, and configured to reset the pull-up module based on a fourth DC voltage signal and a reset signal.

In the embodiments of the disclosure, the input module includes a first transistor, wherein a control electrode of the first transistor is connected with an input port of the start signal, a first electrode of the first transistor is connected with an input port of the first DC voltage signal, and a connection point connecting a second electrode of the first transistor and the pull-up module forms the pull-up point.

In the embodiments of the disclosure, the pull-up module includes a third transistor, an eighth transistor and a first capacitor, wherein a control electrode of the third transistor is connected with the second electrode of the first transistor, a first electrode of the third transistor is connected with an input port of the second DC voltage signal, and a second electrode of the third transistor is connected with the pull-down module, and wherein the second electrode forms the first output port, wherein a control electrode of the eighth transistor is connected with the second electrode of the first transistor, a first electrode of the eighth transistor is connected with an input port of the clock signal, and a second electrode of the eighth transistor is connected with a second port of the first capacitor, and wherein a connection point connecting the second electrode of the eighth transistor and the second port of the first capacitor forms the second output port, wherein a first port of the capacitor is connected with the second electrode of the first transistor, and wherein a connection point connecting the second electrode of the first transistor, the control electrode of the third transistor, the control electrode of the eighth transistor and the first port of the first capacitor forms the pull-up point.

In the embodiments of the disclosure, the pull-down control module includes a fourth transistor, a fifth transistor, a sixth transistor and a ninth transistor, wherein a control electrode of the fourth transistor is connected with the input port of the clock signal, a first electrode of the fourth transistor is connected with a control electrode of the sixth transistor, and a second electrode of the fourth transistor is connected with an input port of the third DC voltage signal, wherein a control electrode and a first electrode of the fifth transistor are each connected with the input port of the second DC voltage signal, and a second electrode of the fifth transistor is connected with the control electrode of the sixth transistor, wherein a first electrode of the sixth transistor is connected with the input port of the second DC voltage signal, and a second electrode of the sixth transistor is connected with the pull-down module, and wherein a control electrode of the ninth transistor is connected with the second electrode of the first transistor, a first electrode of the ninth transistor is connected with the pull-down module, and a second electrode of the ninth transistor is connected with the input port of the third DC voltage signal.

In the embodiments of the disclosure, the pull-down module includes a seventh transistor, a tenth transistor, and an eleventh transistor, wherein a control electrode of the seventh transistor is connected with the second electrode of the sixth transistor, a first electrode of the seventh transistor is connected with the second port of the first capacitor, and a second electrode of the seventh transistor is connected with the input port of the third DC voltage signal, wherein a control electrode of the tenth transistor is connected with the second electrode of the sixth transistor, a first electrode of the tenth transistor is connected with the control electrode of the third transistor, and a second electrode of the tenth transistor is connected with the input port of the third DC voltage signal, wherein a control electrode of the eleventh transistor is connected with the second electrode of the sixth transistor, a first electrode of the eleventh transistor is connected with the second electrode of the third transistor, and a second electrode of the eleventh transistor is connected with the input port of the third DC voltage signal, and wherein, a connection point connecting the control electrode of the seventh transistor, the first electrode of the ninth transistor, the second electrode of the sixth transistor, the control electrode of the tenth transistor and the control electrode of the eleventh transistor forms a pull-down point.

In the embodiments of the disclosure, the reset module includes a second transistor, wherein a control electrode of the second transistor is connected with an input port of the reset signal, a first electrode of the second transistor is connected with the control electrode of the third transistor, and a second electrode of the second transistor is connected with an input port of the fourth DC voltage signal.

In the embodiments of the disclosure, all the transistors from the first transistor to the eleventh transistor are N-type transistors, or wherein all the transistors from the first transistor to the eleventh transistor are P-type transistors, or wherein a part of the transistors from the first transistor to the eleventh transistor are P-type transistors, and the others are N-type transistors.

According to a second aspect of the disclosure, there is provided a gate driving circuit comprising a plurality of shift register units above-mentioned, wherein the plurality of shift register units are connected in cascade, an input module of the shift register unit is inputted with an output signal outputted by the second output port of a previous stage of shift register unit, a reset module of the shift register unit is provided with an output signal outputted by the second output port of a next stage of shift register unit.

According to a third aspect of the disclosure, there is provided a display device comprising a gate driving circuit above-mentioned.

According to a fourth aspect of the disclosure, there is provided a driving method for driving the shift register unit, comprising: a pre-output phase: providing an effective start signal, wherein the pull-up point is charged, and a voltage of the pull-down point is at low level, the first output port outputs a shift signal of which a voltage rises gradually, and a voltage of the second output port is at low level, an output phase: providing an effective clock signal, wherein the charging of pull-up point is completed and a voltage of the pull-up point is at high level, the voltage of the pull-down point is maintained at low level, the first output port outputs a shift signal at high level, and the second output port outputs a start signal at high level for a next stage of shift register unit, a reset phase: providing an effective reset signal, wherein the voltage of the pull-up point is at low level, and the voltage of the pull-down point is at high level, the voltage of the second output port is reset to low level, and the first output port outputs a shift signal at low level, and a maintenance phase: providing an effective clock signal, wherein the voltage of the pull-down point is maintained at high level, and the shift signal outputted by the first output port and the voltage of the second output port are maintained at low level.

In the embodiments of the disclosure, the transistors in the shift register unit are N-type transistors, wherein in the pre-output phase, the start signal is at high level and the clock signal is at low level, the first transistor is ON to charge the pull-up point, the ninth transistor is ON to pull down the voltage of the pull-down point, the eighth transistor is ON, the voltage of the second output port is at low level, and the first output port outputs a shift signal of which the voltage rises gradually, wherein in the output phase, the start signal is at low level and the clock signal is at high level, the eighth transistor is inputted with the voltage of the pull-up point at high level, the voltage of the pull-up point continues to be pulled up and the third transistor is ON, the voltages of the first output port and the second output port are at high level, and the ninth transistor continues to be ON to maintain the voltage of the pull-down point at low level, wherein in the reset phase, the clock signal and the start signal are at low level, the reset signal is at high level, the voltage of the pull-up point is pulled down, the third transistor and the ninth transistor are OFF, the voltage of the pull-down point becomes at high level, the seventh transistor, the tenth transistor and the eleventh transistor are ON, the seventh transistor pulls down the voltage of the second output port, the tenth transistor further pulls down the voltage of the pull-up point, the eleventh transistor pulls down the voltage of the first output port, and the first output port outputs a shift signal at low level, wherein in the maintenance phase, the clock signal is at high level, the voltage of the pull-down point is at high level, the seventh transistor, the tenth transistor and the eleventh transistor maintain to be ON to stabilize the voltage of the pull-up point and maintain the shift signal outputted by the first output port at low level.

In the embodiments of the disclosure, the first DC voltage signal and the fourth DC voltage signal are DC voltage signals with opposite polarities, the second DC voltage signal is a positive voltage signal and the third DC voltage signal is a negative voltage signal.

The shift register unit according to the embodiments of the disclosure uses DC voltage signals (the second DC voltage signal VDD) instead of AC signals as input signals of the pull-up module (i.e., the main transistor M3) and the pull-down control module. In comparison with the prior art using AC voltage signals as input signals, the embodiments of the disclosure have following advantages:

(1) AC signals cause RC delay during transmission, but DC signals do not cause RC delay, so signal delay effect can be reduced.

(2) AC signals cause RC delay, causing attenuation of signals, but DC signals do not have attenuation. Thus, DC signals have stronger driving capabilities than AC signals, and this strengthens driving capabilities.

(3) When driven by AC signals, a parasitic capacitor of the third transistor M3 itself is repeatedly charged and discharged, causing a loss of power. There is no repeated charging and discharging in the process of driving with DC signals, which thus greatly reduces power consumption by the drive circuit. Using DC voltage signals as input signals of the pull-down control module may reduce a number of transistors in case of AC signals, which thus may further reduce power consumption of the drive circuit, enhance the pull-down role of the pull-down point PD, and provide better pull-down capabilities and stable shift signal outputs.

(4) The shift register unit according to the embodiments of the disclosure may further achieve a pre-charging effect (see an oscillogram of the pull-up point PU in FIG. 3).

In addition, the gate driving circuit with the shift register units according to the embodiments of the disclosure may achieve a bi-directional scanning function to make driving more flexible. Furthermore, the display device using the gate driving circuit according to the embodiments of the disclosure may have a small power consumption and present a better display effect.

### DRAWINGS

In order to illustrate the technical solutions of the embodiments of the disclosure more clearly, a brief introduction to figures of the embodiments is made as follows. Apparently, the following figures only relate to some embodiments of the disclosure, but do not limit the disclosure.

FIG. 1 is a schematic structure diagram of the shift register unit according to the embodiments of the disclosure,

FIG. 2 is a schematic circuit diagram of the shift register unit according to the embodiments of the disclosure,

FIG. 3 is a timing oscillogram of the shift register unit according to the embodiments of the disclosure,

FIG. 4 is a schematic structure diagram of the gate driving circuit according to the embodiments of the disclosure.

### DETAILED DESCRIPTION

In order to make technical problems to be solved, technical solutions and advantages of the embodiments of the disclosure clearer, a clear and complete description to the technical solutions of the disclosure shall be made in combination with figures of the embodiments of the disclosure. The embodiments to be described below are only some of embodiments, but not all the embodiments. Based on the described embodiments of the disclosure, those skilled in the art may obtain some other embodiments without creative work, but all the other embodiments shall fall within the protection scope of the disclosure.

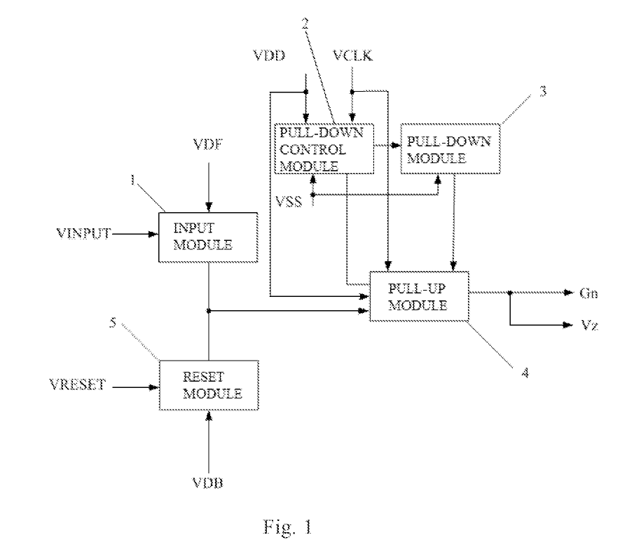

FIG. 1 is a schematic structure diagram of the shift register unit according to the embodiments of the disclosure. As shown by FIG. 1, the embodiments of the disclosure provide a shift register unit which uses DC voltage signals as input signals of the main transistor M3, leading to stable outputs and strong driving capabilities, and which uses DC voltage signals to control transistors of an input module 1 and a pull-down control module 2, significantly reducing power consumption by the circuit in the pull-up phase and the pull-down phase.

An input port of the shift register unit receives input voltage, and an output port thereof provides shift output voltage. The shift register unit comprises an input module 1, a pull-down control module 2, a pull-down module 3, a pull-up module 4 and a reset module 5. The pull-down control module 2 acts on the pull-down module 3. The pull-down module 3 acts on the pull-up module 4. The pull-up module 4 acts on the pull-down control module 2 via a pull-up point.

The input module 1 is connected with the pull-up module 4, and configured to output a pull-up control signal to the pull-up module 4 based on a first DC voltage signal VDF and a start signal Input. The pull-up module 4 is configured to output a shift signal Gn via a first output port out1 and output Vz as a start signal Input for a next stage of shift register unit via a second output port out2, based on a second DC voltage signal VDD and a clock signal CLK. The pull-down control module 2 is connected with the pull-down module 3 and the pull-up module 4, and configured to output a pull-down control signal to the pull-down module 3 based on the second DC voltage signal VDD, a third DC voltage signal VSS and the clock signal CLK. The pull-down module 3 is connected with the pull-up module 4, and configured to output to the pull-up module 4 a pull-down signal for the first output port out1, the second output port out2 and a pull-up point PU. The reset module 5 is connected with the pull-up module 4, and configured to reset the pull-up module 4 based on a fourth DC voltage signal VDB and a reset signal Reset.

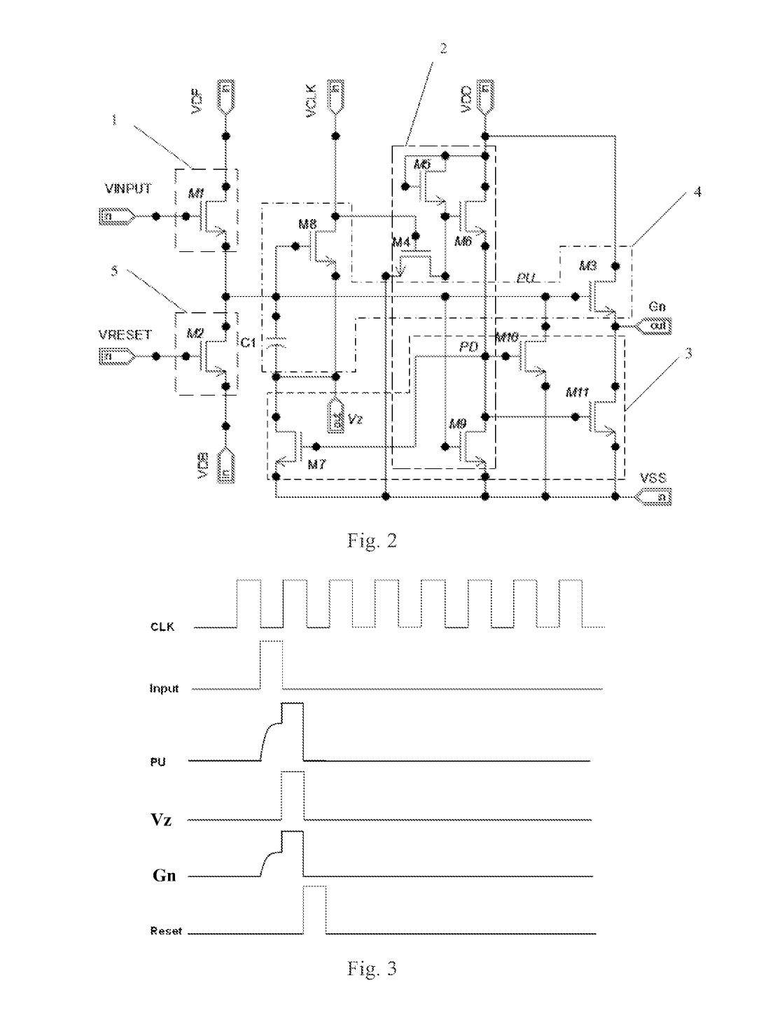

FIG. 2 is a schematic circuit diagram of the shift register unit according to the embodiments of the disclosure. As shown by FIG. 2, the input module 1 includes a first transistor M1, a control electrode of the first transistor M1 is connected with an input port VINPUT of the start signal, a first electrode of the first transistor M1 is connected with an input port of the first DC voltage signal VDF, and a second electrode of the first transistor M1 is connected with the pull-up module 4.

The pull-up module 4 includes a third transistor M3, an eighth transistor M8 and a first capacitor C1. A control electrode of the third transistor M3 is connected with the second electrode of the first transistor M1, a first electrode of the third transistor M3 is connected with an input port of the second DC voltage signal VDD, and a second electrode of the third transistor M3 is connected with the pull-down module 3, wherein the second electrode of the third transistor M3 forms the first output port out1. A control electrode of the eighth transistor M8 is connected with the second electrode of the first transistor M1, a first electrode of the eighth transistor M8 is connected with an input port VCLK of the clock signal, and a second electrode of the eighth transistor M8 is connected with a second port of the first capacitor C1, wherein a connection point connecting the second electrode of the eighth transistor M8 and the second port of the first capacitor C1 forms the second output port out2. A first port of the first capacitor is connected with the second electrode of the first transistor M1. Connection point connecting the second electrode of the first transistor, the control electrode of the third transistor, the control electrode of the eighth transistor and the first port of the first capacitor forms the pull-up point PU.

The pull-down control module 2 includes a fourth transistor M4, a fifth transistor M5, a sixth transistor M6 and a ninth transistor M9. A control electrode of the fourth transistor M4 is connected with the input port VCLK of the clock signal, a first electrode of the fourth transistor M4 is connected with a control electrode of the sixth transistor M6, and a second electrode of the fourth transistor M4 is connected with an input port of the third DC voltage signal VSS. A control electrode and a first electrode of the fifth transistor M5 are each connected with the input port of the second DC voltage signal VDD, and a second electrode of the fifth transistor M5 is connected with the control electrode of the sixth transistor M6. A first electrode of the sixth transistor M6 is connected with the input port of the second DC voltage signal VDD, and a second electrode of the sixth transistor M6 is connected with the pull-down module 3. A control electrode of the ninth transistor M9 is connected with the second electrode of the first transistor M1, a first electrode of the ninth transistor M9 is connected with the pull-down module 3, and a second electrode of the ninth transistor M9 is connected with the input port of the third DC voltage signal VSS.

The pull-down module 3 includes a seventh transistor M7, a tenth transistor M10, and an eleventh transistor M11. A control electrode of the seventh transistor M7 is connected with the second electrode of the sixth transistor, a first electrode of the seventh transistor M7 is connected with the second port of the first capacitor C1, and a second electrode of the seventh transistor M7 is connected with the input port of the third DC voltage signal VSS. A control electrode of the tenth transistor M10 is connected with the second electrode of the sixth transistor M6, a first electrode of the tenth transistor M10 is connected with the control electrode of the third transistor M3, and a second electrode of the tenth transistor M10 is connected with the input port of the third DC voltage signal VSS. A control electrode of the eleventh transistor M11 is connected with the second electrode of the sixth transistor M6, a first electrode of the eleventh transistor M11 is connected with the second electrode of the third transistor M3, and a second electrode of the eleventh transistor M11 is connected with the input port of the third DC voltage signal VSS. A connection point connecting the control electrode of the seventh transistor, the first electrode of the ninth transistor, the second electrode of the sixth transistor, the control electrode of the tenth transistor and the control electrode of the eleventh transistor forms the pull-down point PD.

The reset module 5 includes a second transistor M2, a control electrode of the second transistor M2 is connected with the input port VRESET of the reset signal, a first electrode of the second transistor M2 is connected with the control electrode of the third transistor M3, a second electrode of the second transistor M2 is connected with an input port of the third DC voltage signal.

In the embodiments of the disclosure, all the transistors from the first transistor M1 to the eleventh transistor M11 are N-type transistors, or all the transistors from the first transistor M1 to the eleventh transistor M11 are P-type transistors, or a part of the transistors from the first transistor M1 to the eleventh transistor M11 are P-type transistors, and the others are N-type transistors, as long as corresponding ports of the transistors are correctly connected. In the shift register unit provided by the embodiment, all the transistors are illustrated by taking N-type transistors for instance. Those skilled in the art may conceive of replacing N-type transistors with P-type transistors without creative work, which thus falls within the protection scope of the embodiments of the disclosure.

FIG. 3 is a timing oscillogram of the shift register unit according to the embodiments of the disclosure. As shown by FIG. 3, accordingly, the embodiments of the disclosure further provide a driving method for driving the shift register unit, comprising a pre-output phase, an output phase, a reset phase and a maintenance phase.

In the pre-output phase, the start signal Input is effective, the pull-up point PU is charged, and a voltage of the pull-down point PD is at low level, the first output port out1 outputs a shift signal Gn of which a voltage rises gradually, and a voltage of the second output port is at low level. In the output phase, a clock signal CLK is effective, the charging of the pull-up point PU is completed, a voltage of the pull-up point PU is at high level, the voltage of the pull-down point PD is maintained at low level, the first output port outputs a shift signal Gn at high level, and the second output port out2 outputs a start signal Input at high level for a next stage. In the reset phase, a reset signal Reset is effective, the voltage of the pull-down point PD is at high level, the voltage of the pull-up point PU is at low level. The voltage of the second output port out2 is reset to low level, and the first output port out1 outputs a shift signal Gn at low level. In the maintenance phase, the clock signal CLK is effective, the voltage of the pull-down point PD is maintained at high level, and a shift signal Gn outputted by the first output port out1 and the voltage of the second output port are maintained at low level.

In the embodiments of the disclosure, a further description is made by taking all the transistors from the first transistor M1 to the eleventh transistor M11 being N-type transistors for instance.

In the driving method for driving the shift register unit, at the initial moment, both the start signal Input and the clock signal CLK are at low level, and the voltages of the first output port out1 and the second output port out2 are at low level.

In the pre-output phase, the start signal Input is at high level and the clock signal CLK is at low level, the first transistor M1 is ON to charge the pull-up point PU, when voltage of the pull-down point is high, the ninth transistor M9 is ON to pull down the voltage of the pull-down point PD, the eighth transistor M8 is ON, the first output port out1 outputs a shift signal of which a voltage rises gradually, the second output port out2 outputs low level.

In the output phase, the start signal Input is at low level and the clock signal CLK is at high level, the control electrode of the eighth transistor M8 is inputted with the voltage of the pull-up point PU at high level, the voltage of the pull-up point PU continues to be pulled up by a bootstrap effect of the first capacitor C1, and the third transistor M3 is ON, the voltages of the first output port out1 and the second output port out2 are at high level, and because the voltage of the pull-up point PU is at high level, the ninth transistor M9 continues to be ON to maintain the voltage of the pull-down point PD at low level.

In the reset phase, the clock signal CLK and the start signal Input are at low level, the reset signal Reset is at high level, the second transistor M2 is ON, the fourth DC voltage signal VDB has a DC negative voltage, the voltage of the pull-up point PU is pulled down, the third transistor M3 and the ninth transistor M9 are OFF, the voltage of the pull-down point PD becomes at high level due to an effect from the second DC voltage signal VDD, the tenth transistor M10 and the eleventh transistor M11 are ON, the tenth transistor M10 further pulls down the voltage of the pull-up point PU, the eleventh transistor M11 pulls down the voltage of the first output port out1, the voltage of the first output port out1 is at low level, the seventh transistor M7 is ON and pulls down the voltage of the second output port out2, namely, a start signal Input, i.e., Vz, for the next stage of the shift register unit.

In the maintenance phase, the clock signal CLK is at high level, at this time, the sixth transistor is not OFF, the fourth transistor M4 being ON can only cause a drop of gate electrode voltage of the sixth transistor M6, but the sixth transistor M6 will not be OFF, the voltage of the pull-down point PD is at high level, the seventh transistor M7, the tenth transistor M10 and the eleventh transistor M11 maintain ON to stabilize the voltage of the pull-up point PU and maintain the signal outputted by the first output port out1 at low level.

In the aforesaid process, the pull-down point PD maintains at high level except in the pre-output phase and the output phase. The shift register unit performs a shift register function in the aforesaid order.

In the driving method for driving the shift register unit, the first DC voltage signal VDF and the fourth DC voltage signal VDB are DC voltage signals with opposite polarities, the second DC voltage signal VDD is a positive voltage signal and the third DC voltage signal VSS is a negative voltage signal. For example, when VDF is a DC positive voltage signal and VDB is a DC negative voltage signal, VDF is for starting voltage and VDB is for resetting voltage, when VDF is a DC negative voltage signal and VDB is a DC positive voltage signal, VDF is for resetting voltage and VDB is for starting voltage.

The shift register unit above uses DC voltage signals (the second DC voltage signal VDD) instead of AC signals as input signals of the main transistor M3. In comparison with using AC voltage signals as input signals, the embodiments of the disclosure has the following advantages:

(1) AC signals cause RC delay during transmission, but DC signals do not cause RC delay, so signal delay effect can be reduced.

(2) AC signals cause RC delay, causing attenuation of signals, but DC signals do not have attenuation. Thus, DC signals have stronger driving capabilities than AC signals, and this strengthens driving capabilities.

(3) When driven by AC signals, a parasitic capacitor of the third transistor M3 itself is repeatedly charged and discharged, causing a loss of power. There is no repeated charging and discharging in the process of driving with DC signals, which thus greatly reduces power consumption by the drive circuit. Using DC voltage signals as input signals of the pull-down control module may reduce a number of transistors in case of AC signals, which thus may further reduce power consumption of the drive circuit, enhance the pull-down role of the pull-down point PD, and provide better pull-down capabilities and stable shift signal outputs.

(4) The shift register unit may further achieve a pre-charging effect (see an oscillogram of the pull-up point PU in FIG. 3).

(5) In a liquid display device having a large size, a gate driving circuit composed of a plurality of the shift register units connected in cascade may be used.

The embodiments of the disclosure provide a gate driving circuit, comprising the shift register unit above.

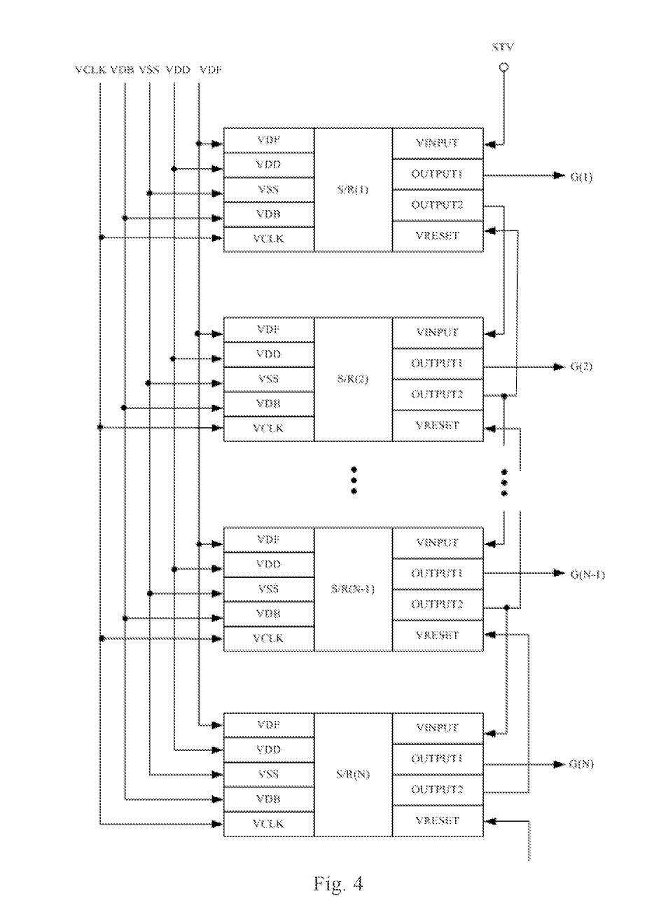

FIG. 4 is a schematic structure diagram of the gate driving circuit according to the embodiments of the disclosure. As shown by FIG. 4, in the gate driving circuit, the input module of the shift register unit at each level controls a signal connection path based on a potential level of the start signal Input, and controls a signal connection path between the DC voltage signal and the output port by a potential level of the pull-up point PU to provide shift signal outputs. Specifically, in the gate driving circuit, a plurality of shift register units are connected in cascade. The output signal Vz outputted by the second output port OUTPUT2 (i.e., out2) is used as a transmission signal. The input module (i.e., the input port VINPUT of the start signal) of a shift register unit is inputted with an output signal Vz outputted by the second output port OUTPUT2 of a previous stage of shift register unit. The reset module (i.e., the input port VRESET of the reset signal) of a shift register unit is provided with an output signal Vz outputted by the second output port OUTPUT2 of a next stage of shift register unit.

Wherein, the second electrode of the first transistor M1 is connected with the first electrode of the second transistor M2. When a scanning sequence is changed, roles of the first transistor M1 in the input module and the second transistor M2 in the reset module are mutually exchanged. That is, if the scanning sequence is reversed, it is only necessary to exchange the start signal Input and the reset signal Reset, change the first triggered GOA unit, and exchange high level and low level of the first DC voltage signal VDF and the fourth DC voltage signal VDB, then, a reverse scanning function can be achieved. For example, during a forward scanning, VDF is a DC positive voltage signal and VDB is a DC negative voltage signal, and during a reverse scanning, VDF is a DC negative voltage signal and VDB is a DC positive voltage signal.

The gate driving circuit in the embodiment has the following advantages:

(1) The shift register units use DC voltage as input signals of the main transistor M3, leading to stable outputs, and strong driving capabilities which are suitable for driving a liquid crystal display device having a large size.

(2) DC signals are used to control transistors of the input module 1 and the pull-down control module 2 of the shift register units, which may significantly reduce power consumption by the circuit in the pull-up phase and the pull-down phase.

(3) A bi-directional scanning function may be achieved to make driving more flexible.

The embodiments of the disclosure provide a display device, comprising the gate driving circuit above-mentioned.

The display device may be any product or component having a display function, such as, liquid crystal panel, electronic paper, OLED panel, mobile telephone, tablet computer, television, display device, laptop, digital photo frame and/or navigator and the like.

The display device may be a display panel having a large size, a small power consumption, and a good display effect.

It is understandable that the aforesaid embodiments are only exemplary embodiments for illustrating the principle of the disclosure. Indeed, the disclosure is not limited to this. Without diverging from spirit and essence of the disclosure, those skilled in the art may make various modifications and improvements to the disclosure, which, however, should be also deemed to fall within the protection scope claimed by the disclosure.

1. A shift register unit comprising an input module, a pull-down control module, a pull-down module, a pull-up module and a reset module,
wherein the input module is connected with the pull-up module, and configured to output a pull-up control signal to the pull-up module based on a first DC voltage signal and a start signal,
wherein the pull-up module is configured to output a shift signal via a first output port and output a start signal for a next stage of shift register unit via a second output port, based on a second DC voltage signal and a clock signal,
wherein the pull-down control module is connected with the pull-down module and the pull-up module, and configured to output a pull-down control signal to the pull-down module based on the second DC voltage signal, a third DC voltage signal and the clock signal,
wherein the pull-down module is connected with the pull-up module, and configured to output to the pull-up module a pull-down signal for the first output port, the second output port and a pull-up point, and
wherein the reset module is connected with the pull-up module, and configured to reset the pull-up module based on a fourth DC voltage signal and a reset signal.

2. The shift register unit according to claim 1, wherein the input module includes a first transistor, wherein a control electrode of the first transistor is connected with an input port of the start signal, a first electrode of the first transistor is connected with an input port of the first DC voltage signal, and a connection point connecting a second electrode of the first transistor and the pull-up module forms the pull-up point.

3. The shift register unit according to claim 2, wherein the pull-up module includes a third transistor, an eighth transistor and a first capacitor,
wherein a control electrode of the third transistor is connected with the second electrode of the first transistor, a first electrode of the third transistor is connected with an input port of the second DC voltage signal, and a second electrode of the third transistor is connected with the pull-down module, and wherein the second electrode forms the first output port,
wherein a control electrode of the eighth transistor is connected with the second electrode of the first transistor, a first electrode of the eighth transistor is connected with an input port of the clock signal, and a second electrode of the eighth transistor is connected with a second port of the first capacitor, and wherein a connection point connecting the second electrode of the eighth transistor and the second port of the first capacitor forms the second output port,
wherein a first port of the capacitor is connected with the second electrode of the first transistor, and
wherein a connection point connecting the second electrode of the first transistor, the control electrode of the third transistor, the control electrode of the eighth transistor and the first port of the first capacitor forms the pull-up point.

4. The shift register unit according to claim 3, wherein the pull-down control module includes a fourth transistor, a fifth transistor, a sixth transistor and a ninth transistor,
wherein a control electrode of the fourth transistor is connected with the input port of the clock signal, a first electrode of the fourth transistor is connected with a control electrode of the sixth transistor, and a second electrode of the fourth transistor is connected with an input port of the third DC voltage signal,
wherein a control electrode and a first electrode of the fifth transistor are each connected with the input port of the second DC voltage signal, and a second electrode of the fifth transistor is connected with the control electrode of the sixth transistor,
wherein a first electrode of the sixth transistor is connected with the input port of the second DC voltage signal, and a second electrode of the sixth transistor is connected with the pull-down module, and
wherein a control electrode of the ninth transistor is connected with the second electrode of the first transistor, a first electrode of the ninth transistor is connected with the pull-down module, and a second electrode of the ninth transistor is connected with the input port of the third DC voltage signal.

5. The shift register unit according to claim 4, wherein the pull-down module includes a seventh transistor, a tenth transistor, and an eleventh transistor,
wherein a control electrode of the seventh transistor is connected with the second electrode of the sixth transistor, a first electrode of the seventh transistor is connected with the second port of the first capacitor, and a second electrode of the seventh transistor is connected with the input port of the third DC voltage signal,
wherein a control electrode of the tenth transistor is connected with the second electrode of the sixth transistor, a first electrode of the tenth transistor is connected with the control electrode of the third transistor, and a second electrode of the tenth transistor is connected with the input port of the third DC voltage signal,
wherein a control electrode of the eleventh transistor is connected with the second electrode of the sixth transistor, a first electrode of the eleventh transistor is connected with the second electrode of the third transistor, and a second electrode of the eleventh transistor is connected with the input port of the third DC voltage signal, and
wherein, a connection point connecting the control electrode of the seventh transistor, the first electrode of the ninth transistor, the second electrode of the sixth transistor, the control electrode of the tenth transistor and the control electrode of the eleventh transistor forms a pull-down point.

6. The shift register unit according to claim 5, wherein the reset module includes a second transistor, wherein a control electrode of the second transistor is connected with an input port of the reset signal, a first electrode of the second transistor is connected with the control electrode of the third transistor, and a second electrode of the second transistor is connected with an input port of the fourth DC voltage signal.

7. The shift register unit according to claim 6, wherein all the transistors from the first transistor to the eleventh transistor are N-type transistors, or
wherein all the transistors from the first transistor to the eleventh transistor are P-type transistors, or
wherein a part of the transistors from the first transistor to the eleventh transistor are P-type transistors, and the others are N-type transistors.

8. A gate driving circuit comprising a plurality of shift register units according to claim 1, wherein the plurality of shift register units are connected in cascade, an input module of the shift register unit is inputted with an output signal outputted by the second output port of a previous stage of shift register unit, a reset module of the shift register unit is provided with an output signal outputted by the second output port of a next stage of shift register unit.

9. A display device comprising a gate driving circuit according to claim 8.

10. A driving method for driving a shift register unit according to claim 1, comprising:
a pre-output phase: providing an effective start signal, wherein the pull-up point is charged, and a voltage of the pull-down point is at low level, the first output port outputs a shift signal of which a voltage rises gradually, and a voltage of the second output port is at low level,
an output phase: providing an effective clock signal, wherein the charging of pull-up point is completed and a voltage of the pull-up point is at high level, the voltage of the pull-down point is maintained at low level, the first output port outputs a shift signal at high level, and the second output port outputs a start signal at high level for a next stage of shift register unit,
a reset phase: providing an effective reset signal, wherein the voltage of the pull-up point is at low level, and the voltage of the pull-down point is at high level, the voltage of the second output port is reset to low level, and the first output port outputs a shift signal at low level, and
a maintenance phase: providing an effective clock signal, wherein the voltage of the pull-down point is maintained at high level, and the shift signal outputted by the first output port and the voltage of the second output port are maintained at low level.

11. The driving method according to claim 10, wherein the transistors in the shift register unit are N-type transistors,
wherein in the pre-output phase, the start signal is at high level and the clock signal is at low level, the first transistor is ON to charge the pull-up point, the ninth transistor is ON to pull down the voltage of the pull-down point, the eighth transistor is ON, the voltage of the second output port is at low level, and the first output port outputs a shift signal of which the voltage rises gradually,
wherein in the output phase, the start signal is at low level and the clock signal is at high level, the eighth transistor is inputted with the voltage of the pull-up point at high level, the voltage of the pull-up point continues to be pulled up and the third transistor is ON, the voltages of the first output port and the second output port are at high level, and the ninth transistor continues to be ON to maintain the voltage of the pull-down point at low level,
wherein in the reset phase, the clock signal and the start signal are at low level, the reset signal is at high level, the voltage of the pull-up point is pulled down, the third transistor and the ninth transistor are OFF, the voltage of the pull-down point becomes at high level, the seventh transistor, the tenth transistor and the eleventh transistor are ON, the seventh transistor pulls down the voltage of the second output port, the tenth transistor further pulls down the voltage of the pull-up point, the eleventh transistor pulls down the voltage of the first output port, and the first output port outputs a shift signal at low level,
wherein in the maintenance phase, the clock signal is at high level, the voltage of the pull-down point is at high level, the seventh transistor, the tenth transistor and the eleventh transistor maintain to be ON to stabilize the voltage of the pull-up point and maintain the shift signal outputted by the first output port at low level.

12. The driving method according to claim 11, wherein the first DC voltage signal and the fourth DC voltage signal are DC voltage signals with opposite polarities, the second DC voltage signal is a positive voltage signal and the third DC voltage signal is a negative voltage signal.

13. The gate driving circuit according to claim 8, wherein the input module includes a first transistor, wherein a control electrode of the first transistor is connected with an input port of the start signal, a first electrode of the first transistor is connected with an input port of the first DC voltage signal, and a connection point connecting a second electrode of the first transistor and the pull-up module forms the pull-up point.

14. The gate driving circuit according to claim 13, wherein the pull-up module includes a third transistor, an eighth transistor and a first capacitor,
wherein a control electrode of the third transistor is connected with the second electrode of the first transistor, a first electrode of the third transistor is connected with an input port of the second DC voltage signal, and a second electrode of the third transistor is connected with the pull-down module, and wherein the second electrode forms the first output port,
wherein a control electrode of the eighth transistor is connected with the second electrode of the first transistor, a first electrode of the eighth transistor is connected with an input port of the clock signal, and a second electrode of the eighth transistor is connected with a second port of the first capacitor, and wherein a connection point connecting the second electrode of the eighth transistor and the second port of the first capacitor forms the second output port,
wherein a first port of the capacitor is connected with the second electrode of the first transistor, and
wherein a connection point connecting the second electrode of the first transistor, the control electrode of the third transistor, the control electrode of the eighth transistor and the first port of the first capacitor forms the pull-up point.

15. The gate driving circuit according to claim 14, wherein the pull-down control module includes a fourth transistor, a fifth transistor, a sixth transistor and a ninth transistor,
wherein a control electrode of the fourth transistor is connected with the input port of the clock signal, a first electrode of the fourth transistor is connected with a control electrode of the sixth transistor, and a second electrode of the fourth transistor is connected with an input port of the third DC voltage signal,
wherein a control electrode and a first electrode of the fifth transistor are each connected with the input port of the second DC voltage signal, and a second electrode of the fifth transistor is connected with the control electrode of the sixth transistor,
wherein a first electrode of the sixth transistor is connected with the input port of the second DC voltage signal, and a second electrode of the sixth transistor is connected with the pull-down module, and
wherein a control electrode of the ninth transistor is connected with the second electrode of the first transistor, a first electrode of the ninth transistor is connected with the pull-down module, and a second electrode of the ninth transistor is connected with the input port of the third DC voltage signal.

16. The gate driving circuit according to claim 15, wherein the pull-down module includes a seventh transistor, a tenth transistor, and an eleventh transistor,
wherein a control electrode of the seventh transistor is connected with the second electrode of the sixth transistor, a first electrode of the seventh transistor is connected with the second port of the first capacitor, and a second electrode of the seventh transistor is connected with the input port of the third DC voltage signal,
wherein a control electrode of the tenth transistor is connected with the second electrode of the sixth transistor, a first electrode of the tenth transistor is connected with the control electrode of the third transistor, and a second electrode of the tenth transistor is connected with the input port of the third DC voltage signal,
wherein a control electrode of the eleventh transistor is connected with the second electrode of the sixth transistor, a first electrode of the eleventh transistor is connected with the second electrode of the third transistor, and a second electrode of the eleventh transistor is connected with the input port of the third DC voltage signal, and
wherein, a connection point connecting the control electrode of the seventh transistor, the first electrode of the ninth transistor, the second electrode of the sixth transistor, the control electrode of the tenth transistor and the control electrode of the eleventh transistor forms a pull-down point.

17. The gate driving circuit according to claim 16, wherein the reset module includes a second transistor, wherein a control electrode of the second transistor is connected with an input port of the reset signal, a first electrode of the second transistor is connected with the control electrode of the third transistor, and a second electrode of the second transistor is connected with an input port of the fourth DC voltage signal.

18. The driving method according to claim 10, wherein the input module includes a first transistor, wherein a control electrode of the first transistor is connected with an input port of the start signal, a first electrode of the first transistor is connected with an input port of the first DC voltage signal, and a connection point connecting a second electrode of the first transistor and the pull-up module forms the pull-up point.

19. The driving method according to claim 18, wherein the pull-up module includes a third transistor, an eighth transistor and a first capacitor,
wherein a control electrode of the third transistor is connected with the second electrode of the first transistor, a first electrode of the third transistor is connected with an input port of the second DC voltage signal, and a second electrode of the third transistor is connected with the pull-down module, and wherein the second electrode forms the first output port,
wherein a control electrode of the eighth transistor is connected with the second electrode of the first transistor, a first electrode of the eighth transistor is connected with an input port of the clock signal, and a second electrode of the eighth transistor is connected with a second port of the first capacitor, and wherein a connection point connecting the second electrode of the eighth transistor and the second port of the first capacitor forms the second output port,
wherein a first port of the capacitor is connected with the second electrode of the first transistor, and
wherein a connection point connecting the second electrode of the first transistor, the control electrode of the third transistor, the control electrode of the eighth transistor and the first port of the first capacitor forms the pull-up point.

20. The driving method according to claim 19, wherein the pull-down control module includes a fourth transistor, a fifth transistor, a sixth transistor and a ninth transistor,
wherein a control electrode of the fourth transistor is connected with the input port of the clock signal, a first electrode of the fourth transistor is connected with a control electrode of the sixth transistor, and a second electrode of the fourth transistor is connected with an input port of the third DC voltage signal,
wherein a control electrode and a first electrode of the fifth transistor are each connected with the input port of the second DC voltage signal, and a second electrode of the fifth transistor is connected with the control electrode of the sixth transistor,
wherein a first electrode of the sixth transistor is connected with the input port of the second DC voltage signal, and a second electrode of the sixth transistor is connected with the pull-down module, and
wherein a control electrode of the ninth transistor is connected with the second electrode of the first transistor, a first electrode of the ninth transistor is connected with the pull-down module, and a second electrode of the ninth transistor is connected with the input port of the third DC voltage signal.
